(19) United States
(12) Patent Application Publication
(10) Pub. No.: US 2023/0242723 A1
(43) Pub. Date: Aug. 3, 2023

(54) FILM AND LAMINATE

(71) Applicant: FUJIFILM Corporation, Tokyo (JP)

(72) Inventors: Miyoko HARA, Kanagawa (JP); Yasuyuki Sasada, Kanagawa (JP)

(73) Assignee: FUJIFILM Corporation, Tokyo (JP)

(21) Appl. No.: 18/154,874

(22) Filed: Jan. 16, 2023

(30) Foreign Application Priority Data
Jan. 31, 2022 (JP) 2022-013110

(51) Int. Cl. C08J 5/18; C08K 7/22

(52) U.S. Cl. CPC C08J 5/18; C08K 7/22; C08J 2377/12; C08J 2467/03

(57) ABSTRACT

Provided are a film which includes at least an aromatic polyester amide, and hasa melting calorie equal to or greater than 2.2 J/g; a laminate which includes at least the film and a metal layer or a metal wire which is disposed on at least one surface of the film; and applications of the film.

### CROSS REFERENCE TO RELATED APPLICATIONS

The present application claims priority under 35 U.S.C. §119 to Japanese Patent Application No. 2022-013110 filed on Jan. 31, 2022. The above application is hereby expressly incorporated by reference, in its entirety, into the present application.

### BACKGROUND OF THE INVENTION

### 1. Field of the Invention

The present disclosure relates to a film and a laminate.

### 2. Description of the Related Art

In recent years, a frequency that is used in communication equipment tends to be extremely high. To suppress a transmission loss in a high frequency band, it has been required to decrease a specific dielectric constant and a dielectric loss tangent of an insulation material that is used in a circuit board. In the related art, while polyimide is often used as the insulation material that is used in the circuit board, a liquid crystal polymer that has high heat resistance and low water absorption and is small in transmission loss in the high frequency band is attracting attention.

For example, JP2020-026474A describes a liquid crystalline polyester film that contains at least liquid crystalline polyester, in which, in a case where a first alignment degree is set to an alignment degree with respect to a first direction parallel to a main surface of the liquid crystalline polyester film, and a second alignment degree is set to an alignment degree with respect to a second direction parallel to the main surface and perpendicular to the first direction, a first alignment degree/second alignment degree that is a ratio of the first alignment degree and the second alignment degree is equal to or greater than 0.95 and equal to or less than 1.04, and a third alignment degree of the liquid crystalline polyester that is measured by a wide angle X-ray scattering method in a direction parallel to the main surface is equal to or greater than 60.0%.

### SUMMARY OF THE INVENTION

An object of an embodiment of the present invention is to provide a film and a laminate that have a low dielectric loss tangent compared to the related art.

Means for attaining the above-described object includes the following aspects. <1> A film comprising aromatic polyester amide, in which the film has a melting calorie equal to or greater than 2.2 J/g.

<2> The film according to <1>, in which a melting point of the film is 300° C. to 360° C.

<3> The film according to <2>, in which a ratio of the melting calorie to the melting point is equal to or greater than 0.007 J/g·°C.

<4> The film according to any one of <1> to <3>, in which the aromatic polyester amide contains a constitutional unit represented by Formula 1, a constitutional unit represented by Formula 2, and a constitutional unit represented by Formula 3,
with respect to a total content of the constitutional unit represented by Formula 1, the constitutional unit represented by Formula 2, and the constitutional unit represented by Formula 3,
a content of the constitutional unit represented by Formula 1 is 30% by mol to 80% by mol,
a content of the constitutional unit represented by Formula 2 is 10% by mol to 35% by mol, and
a content of the constitutional unit represented by Formula 3 is 10% by mol to 35% by mol,

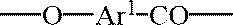

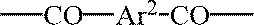

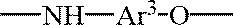

in Formula 1 to Formula 3, Ar¹, Ar², and Ar³ each independently represent a phenylene group, a naphthylene group, or a biphenylylene group.

<5> The film according to any one of <1> to <4>, further comprising a filler.

<6> The film according to <5>, in which the filler includes an inorganic filler containing at least one selected from the group consisting of boron nitride, titanium dioxide, and silicon dioxide.

<7> The film according to <5> or <6>, in which the filler includes an organic filler containing at least one selected from the group consisting of liquid crystalline polyester, polytetrafluoroethylene, and polyethylene.

<8> The film according to any one of <5> to <7>, in which the filler contains hollow particles.

<9> The film according to <5>, in which the filler contains liquid crystal polymer particles, silica particles, or glass hollow particles.

<10> A laminate comprising the film according to any one of <1> to <9>, and a metal layer or a metal wire, disposed on at least one surface of the film.

According to the embodiment of the present invention, a film and a laminate that have a low dielectric loss tangent compared to the related art are provided.

### DESCRIPTION OF THE PREFERRED EMBODIMENTS

Hereinafter, the content of the present disclosure will be described in detail. The description of the constituent elements described below will be made based on a representative embodiment of the present disclosure, but the present disclosure is not limited to such an embodiment.

In the present specification, “to” indicating a numerical range is used in a meaning including numerical values described before and after “to” as a lower limit value and an upper limit value.

In numerical ranges described in stages in the present disclosure, an upper limit value and a lower limit value described in one numerical range may be substituted with an upper limit value and a lower limit value of another numerical range described in another stage. In the numerical ranges described in the present disclosure, an upper limit value and a lower limit value of the numerical ranges may be substituted with values shown in examples.

In a case where substitution or unsubstitution is not noted in regard to the notation of a group (atomic group) in the present specification, the group includes not only a group having no substituent but also a group having a substituent. For example, “alkyl group” denotes not only an alkyl group (unsubstituted alkyl group) having no substituent but also an alkyl group (substituted alkyl group) having a substituent.

In the present disclosure, a combination of two or more preferred aspects is a more preferred aspect.

A weight-average molecular weight (Mw) and a number-average molecular weight (Mn) in the present disclosure are molecular weights in terms of polystyrene used as a standard substance, which are detected by a solvent pentafluorophenol (PFP)/chloroform = ½ (mass ratio) and a differential refractometer using gel permeation chromatography (GPC) analyzer using TSKgel SuperHM-H (product name manufactured by Tosoh Corporation) as a column, unless otherwise specified.

### Film

A film of the present disclosure includes aromatic polyester amide, and has a melting calorie equal to or greater than 2.2 J/g.

The present inventors have conducted intensive studies and have found that the above-described configuration is made, whereby it is possible to provide a film that has a low dielectric loss tangent compared to the related art.

A detailed mechanism with which the above-described effect is obtained is unclear, but is presumed as follows.

In the film of the present disclosure, since the melting calorie is equal to or greater than 2.2 J/g, it is considered that a crystallization amount in the film is large and mobility of a non-crystallized portion decreases, such that the dielectric loss tangent decreases.

On the other hand, JP2020-026474A does not focus on a dielectric loss tangent, and a liquid crystalline polyester film described in JP2020-026474A has a low degree of crystallinity.

### Aromatic Polyester Amide

The film of the present disclosure includes aromatic polyester amide. Aromatic polyester amide is resin having at least one aromatic ring and having an ester bond and an amide bond. Aromatic polyester amide included in a resin layer is preferably fully aromatic polyester amide among the substances from a viewpoint of heat resistance.

Aromatic polyester amide is preferably a crystalline polymer. The film of the present disclosure preferably includes crystalline aromatic polyester amide. Aromatic polyester amide included in the film is crystalline, whereby the dielectric loss tangent further decreases.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature increase rate 10° C./minute is within 10° C. A polymer in which a half-width exceeds 10° C. and a polymer in which a clear endothermic peak is not recognized are distinguished as an amorphous polymer from a crystalline polymer.

A melting point of aromatic polyester amide is preferably equal to or higher than 250° C., more preferably 250° C. to 350° C., and still more preferably 320° C. to 340° C.

The melting point is measured using a differential scanning calorimetry apparatus. For example, the measurement is performed using product name “DSC-60A Plus” (manufactured by Shimadzu Corporation). A temperature increase rate in the measurement is set to 10° C./minute.

Aromatic polyester amide has a melting calorie preferably equal to or greater than 2.2 J/g, more preferably equal to or greater than 4.0 J/g, and still more preferably equal to or greater than 7.0 J/g. An upper limit value of the melting calorie is not particularly limited, and is, for example, 10.0 J/g. A measurement method of the melting calorie is the same as a measurement method of a melting calorie of a film described below.

Aromatic polyester amide preferably contains a constitutional unit represented by Formula 1, a constitutional unit represented by Formula 2, and a constitutional unit represented by Formula 3.

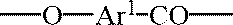

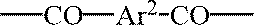

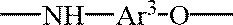

In Formula 1 to Formula 3, Ar¹, Ar², and Ar³ each independently represent a phenylene group, a naphthylene group, or a biphenylylene group.

Hereinafter, the constitutional unit represented by Formula 1 and the like are also referred to as a “unit 1” and the like.

The unit 1 can be introduced, for example, using aromatic hydroxy carboxylic acid as a raw material.

The unit 2 can be introduced, for example, using aromatic dicarboxylic acid as a raw material.

The unit 3 can be introduced, for example, using aromatic hydroxylamine as a raw material.

Here, aromatic hydroxy carboxylic acid, aromatic dicarboxylic acid, aromatic diol, and aromatic hydroxylamine may be each independently substituted with a polycondensable derivative.

For example, aromatic hydroxy carboxylic acid and aromatic dicarboxylic acid can be substituted with aromatic hydroxy carboxylic acid ester and aromatic dicarboxylic acid ester by converting a carboxy group into an alkoxycarbonyl group or an aryloxycarbonyl group.

Aromatic hydroxy carboxylic acid and aromatic dicarboxylic acid can be substituted with aromatic hydroxy carboxylic acid halide and aromatic dicarboxylic acid halide by converting a carboxy group into a haloformyl group.

Aromatic hydroxy carboxylic acid and aromatic dicarboxylic acid can be substituted with aromatic hydroxy carboxylic acid anhydride and aromatic dicarboxylic acid anhydride by converting a carboxy group into an acyloxycarbonyl group.

Examples of a polycondensable derivative of a compound having a hydroxy group, such as aromatic hydroxy carboxylic acid or aromatic hydroxyamine, include a substance (acylated substance) obtained by acylating the hydroxy group to convert the hydroxy group into an acyloxy group.

For example, aromatic hydroxy carboxylic acid and aromatic hydroxylamine can be each substituted with an acylated substance by acylating a hydroxy group to convert the hydroxy group into an acyloxy group.

An example of a polycondensable derivative of aromatic hydroxylamine is a substance (acylated substance) obtained by acylating an amino group to convert the amino group into an acylamino group.

For example, aromatic hydroxyamine can be substituted with an acylated substance by acylating an amino group to convert the amino group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar¹ is a 2,6-naphthylene group, the unit 1 is, for example, a constitutional unit derived from 6-hydroxy-2-naphthoic acid.

In a case where Ar¹ is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a constitutional unit derived from p-aminophenol.

In a case where Ar³ is a 4,4′-biphenylylene group, the unit 3 is, for example, a constitutional unit derived from 4-amino-4′-hydroxybiphenyl.

With respect to a total content of the unit 1, the unit 2, and the unit 3, a content of the unit 1 is preferably equal to or greater than 30% by mol, a content of the unit 2 is preferably equal to or less than 35% by mol, and a content of the unit 3 is preferably equal to or less than 35% by mol.

The content of the unit 1 is preferably 30% by mol to 80% by mol, more preferably 30% by mol to 60% by mol, and particularly preferably 30% by mol to 40% by mol, with respect to the total content of the unit 1, the unit 2, and the unit 3.

The content of the unit 2 is preferably 10% by mol to 35% by mol, more preferably 20% by mol to 35% by mol, and particularly preferably 30% by mol to 35% by mol, with respect to the total content of the unit 1, the unit 2, and the unit 3.

The content of the unit 3 is preferably 10% by mol to 35% by mol, more preferably 20% by mol to 35% by mol, and particularly preferably 30% by mol to 35% by mol, with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

A ratio of the content of the unit 2 and the content of the unit 3 is preferably 0.9/1 to ⅟0.9, more preferably 0.95/1 to ⅟0.95, and still more preferably 0.98/1 to ⅟0.98 in a case of being represented by [content of unit 2]/[the content of the unit 3] (mol/mol).

Aromatic polyester amide may have two kinds or more of the unit 1 to the unit 3 each independently. Alternatively, aromatic polyester amide may have other constitutional units other than the unit 1 to the unit 3. A content of other constitutional units is preferably equal to or less than 10% by mol, and more preferably equal to or less than 5% by mol, with respect to a total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

The film of the present disclosure may contain only one kind of aromatic polyester amide or may contain two kinds or more of aromatic polyester amide.

A content of aromatic polyester amide is preferably equal to or greater than 50% by mass, more preferably equal to or greater than 70% by mass, and still more preferably equal to or greater than 90% by mass, with respect to a total amount of the film. An upper limit value of the content of aromatic polyester amide is not particularly limited, and may be 100% by mass.

### Filler

The film according to the present disclosure preferably includes a filler.

The filler may be particulate or fibrous, and may be an inorganic filler or an organic filler.

As the inorganic filler, a known inorganic filler can be used.

Examples of a material of the inorganic filler include boron nitride (BN), aluminum oxide (Al₂O₃), aluminum nitride (AlN), titanium dioxide (TiO₂), silicon dioxide (SiO₂), barium titanate, strontium titanate, aluminum hydroxide, calcium carbonate, and a material including two kinds or more thereof.

From a viewpoint of decreasing the dielectric loss tangent of the film, the inorganic filler preferably includes an inorganic filler containing at least one selected from the group consisting of boron nitride, titanium dioxide, and silicon dioxide, and is more preferably a material (so-called silica particles) including silicon dioxide.

Alternatively, the inorganic filler may be hollow particles. As a hollow inorganic filler, hollow particles (glass hollow particles) including silicon dioxide are preferably used. An example of hollow particles is a glass bubbles series (for example, glass bubbles S60HS) manufactured by 3M Japan Limited.

The inorganic filler is preferably silica particles that are solid particles including silicon dioxide or glass hollow particles that are hollow particles including silicon dioxide.

From a viewpoint of a thermal expansion coefficient and adhesiveness to metal, an average particle diameter of the inorganic filler is preferably 5 nm to 40 µm, more preferably 1 µm to 35 µm, still more preferably 5 µm to 35 µm, and particularly preferably 10 µm to 35 µm. In a case where particles or fibers are flat, the average particle diameter indicates a length in a short side direction.

The average particle diameter of the inorganic filler is a particle diameter (D50) in a case where volume accumulation from a small diameter side is 50% in a volume-based particle size distribution. D50 can be measured using a scanning electron microscope (SEM).

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer (LCP), and a material including two kinds or more thereof.

From a viewpoint of decreasing the dielectric loss tangent of the film, the organic filler preferably includes an organic filler containing at least one selected from the group consisting of a liquid crystal polymer, fluororesin, and polyethylene, more preferably includes at least one kind selected from the group consisting of liquid crystalline polyester, polytetrafluoroethylene, and polyethylene, and still more preferably includes liquid crystalline polyester.

The liquid crystal polymer that is a kind of the organic filler is liquid crystal polymer particles and is distinguished from the liquid crystal polymer included in the film.

Here, the organic filler (also referred to as “liquid crystal polymer particles”) including the liquid crystal polymer can be produced, for example, by polymerizing the liquid crystal polymer and grinding the liquid crystal polymer into powder by a grinder or the like.

Alternatively, the organic filler may be fibrous, such as nanofibers, or may be hollow resin particles.

From a viewpoint of a thermal expansion coefficient and adhesiveness to metal, an average particle diameter of the organic filler is preferably 5 nm to 20 µm, more preferably 1 µm to 20 µm, still more preferably 5 µm to 15 µm, and particularly preferably 10 µm to 15 µm.

The average particle diameter of the organic filler is a particle diameter (D50) in a case where volume accumulation from a small diameter side is 50% in a volume-based particle size distribution. D50 can be measured using a scanning electron microscope (SEM).

From a viewpoint of decreasing the dielectric loss tangent of the film, the filler preferably contains hollow particles.

In particular, from a viewpoint of decreasing the dielectric loss tangent of the film, the filler more preferably contains liquid crystal polymer particles, silica particles, or glass hollow particles.

In a case where the film includes the filler, a content of the filler is preferably 20% by volume to 80% by volume, and more preferably 40% by volume to 80% by volume, with respect to the total volume of the film

The film of the present disclosure may contain other components other than aromatic polyester amide and the filler as long as the effects of the present disclosure are not significantly impaired.

As other components, known additives can be used. Examples of other components include a leveling agent, an antifoaming agent, an antioxidant, an ultraviolet absorbent, a flame retardant, and a colorant.

### Physical Property

### Melting Calorie

A melting calorie of the film of the present disclosure is equal to or greater than 2.2 J/g, preferably equal to or greater than 4.0 J/g, and more preferably equal to or greater than 7.0 J/g. An upper limit value of the melting calorie is not particularly limited, and is, for example, 10.0 J/g.

In the present disclosure, the melting calorie indicates a calorie (latent heat) necessary for phase transition of a solid film to a liquid, and is a value that is measured using a differential scanning calorimeter. The melting calorie is measured, for example, using product name “DSC-60A Plus” (manufactured by Shimadzu Corporation). A temperature increase rate in the measurement is set to 10° C./minute.

The film of the present disclosure has a high degree of crystallinity and a low dielectric loss tangent since the melting calorie is equal to or greater than 2.2 J/g. The melting calorie of the film of the present disclosure can be controlled by appropriately selecting conditions, such as a temperature and a time during heating, and a temperature decrease rate during cooling.

### Melting Point

A melting point of the film of the present disclosure is preferably 300° C. to 360° C., and more preferably 320° C. to 350° C.

In the present disclosure, the melting point is a value that is measured using a differential scanning calorimeter. The measurement is performed, for example, using product name “DSC-60A Plus” (manufactured by Shimadzu Corporation) as the differential scanning calorimeter. A temperature increase rate in the measurement is set to 10° C./minute.

### Ratio of Melting Calorie to Melting Point

From a viewpoint of further decreasing the dielectric loss tangent, in the film the present disclosure, a ratio of the melting calorie to the melting point is preferably equal to or greater than 0.007 J/g- °C. An upper limit value of the ratio is not particularly limited, and is, for example, 0.02 J/g- °C.

### Dielectric Loss Tangent

The dielectric loss tangent of the film of the present disclosure is preferably equal to or less than 0.005, more preferably equal to or less than 0.004, and still more preferably equal to or less than 0.003. In the present disclosure, the measurement of the dielectric loss tangent is performed by a resonance perturbation method at a frequency of 10 GHz. A 10 GHz cavity resonator (CP531 manufactured by KANTO Electronic Application and Development Inc.) is connected to a network analyzer (“E8363B” manufactured by Agilent Technology Co., Ltd.), a test piece is inserted into the cavity resonator, and the dielectric loss tangent of the film is measured from change in resonance frequency before and after insertion for 96 hours under an environment of a temperature of 25° C. and humidity of 60 %RH.

### Thickness

A thickness of the film of the present disclosure is preferably 6 µm to 200 µm, more preferably 12 µm to 100 µm, and still more preferably 20 µm to 60 µm from a viewpoint of strength, the dielectric loss tangent, and adhesiveness to a metal layer.

The thickness of the film is measured at any five places using an adhesive film thickness meter. The measurement is performed, for example, using an electronic micrometer (product name “KG3001A”, manufactured by Anritsu Corporation) as a film thickness meter, and an average value of the measured values is employed.

### Manufacturing Method of Film

The film of the present disclosure can be manufactured by a known method. For example, a resin solution or a resin dispersion liquid including aromatic polyester amide is coated on a substrate by a casting method to form a resin layer, and then, the substrate is peeled, whereby the resin layer can be obtained as a film. A metal substrate is used as the substrate, whereby a laminate having a metal layer and the resin layer (film) can be obtained. The substrate may not be peeled depending on purposes.

The resin solution preferably contains aromatic polyester amide and a solvent. The resin dispersion liquid preferably contains aromatic polyester amide, a filler, and a solvent.

Examples of the solvent include halogenated hydrocarbon, such as dichloromethane, chloroform, 1,1-dichloroethane, 1,2-dichloroethane, 1,1,2,2-tetrachloroethane, 1-chlorobutane, chlorobenzene, or o-dichlorobenzene; halogenated phenol, such as p-chlorophenol, pentachlorophenol, or pentafluorophenol; ether, such as diethyl ether, tetrahydrofuran, or 1,4-dioxane; ketone, such as acetone or cyclohexanone; ester, such as ethyl acetate or γ-butyrolactone; carbonate, such as ethylene carbonate or propylene carbonate; amine, such as triethylamine; a nitrogen-containing heterocyclic aromatic compound, such as pyridine; nitrile, such as acetonitrile or succinonitrile; amide, such as N,N-dimethylformamide, N,N-dimethylacetamide, or N-methylpyrrolidone; a urea compound, such as tetramethylurea; a nitro compound, such as nitromethane or nitrobenzene; a sulfur compound, such as dimethyl sulfoxide or sulfolane; and phosphorus compound, such as hexamethylphosphoramide or tri-n-butyl phosphate.

The solvent preferably contains an aprotic compound, and in particular, an aprotic compound having no halogen atom among the solvents for low corrosiveness and easiness to handle. A proportion of the aprotic compound to the whole solvent is preferably 50% by mass to 100% by mass, more preferably 70% by mass to 100% by mass, and particularly preferably 90% by mass to 100% by mass. For easiness to dissolve aromatic polyester amide, the aprotic compound is preferably amide, such as N,N-dimethylformamide, N,N-dimethylacetamide, or N-methylpyrrolidone, or ester, such as γ-butyrolactone, and more preferably N,N-dimethylformamide, N,N-dimethylacetamide, or N-methylpyrrolidone.

After the resin solution or the resin dispersion liquid is coated on the substrate, heating is preferably performed. A heating temperature is, for example, 40° C. to 100° C. A heating time is, for example, 10 minutes to 5 hours.

After the resin layer is formed on the substrate, and annealing treatment is preferably performed on a laminate including the substrate and the resin layer. The melting calorie of the film can be adjusted by a temperature and a time of the annealing treatment. To set the melting calorie of the film to be equal to or greater than 2.2 J/g, the annealing treatment is preferably performed at 250° C. to 350° C. for 2.5 hours to 10 hours. The annealing treatment is preferably performed under an inert gas atmosphere, such as nitrogen.

### Laminate

The laminate of the present disclosure preferably includes the film, and a metal layer or a metal wire disposed on at least one surface of the film.

The metal layer or the metal wire may be a known metal layer or metal wire, and examples of metal include copper, silver, gold, and an alloy thereof. The metal layer or the metal wire is preferably a copper layer or a copper wire.

The copper layer is preferably a rolled copper foil formed by a rolling method or an electrolytic copper foil formed by an electrolytic method.

The laminate may be manufactured by laminating the film and the metal layer.

As a method for laminating the film and the metal layer is not particularly limited, and a known laminating method can be used.

The metal substrate is used as the substrate in the manufacturing method of the film, whereby the laminate can be manufactured without peeling the film from the substrate.

A thickness of the metal layer is not particularly limited, and is preferably 3 µm to 30 µm, and more preferably 5 µm to 20 µm.

The thickness of the metal layer is calculated by the following method.

The laminate is cut with a microtome, and a cross section is observed with an optical microscope. Three or more cross section samples are cut, and a thickness of a layer to be measured in each cross section is measured at three points or more. An average value of the measured values is calculated, and an average thickness is employed.

The metal layer in the laminate of the present disclosure is, for example, preferably processed in a desired circuit pattern by etching to form a flexible printed circuit board. An etching method is not particularly limited, and a known etching method can be used. Examples

Hereinafter, while the present disclosure will be more specifically described by examples, the present disclosure is not limited to the following examples within a range departing from the gist thereof.

### Synthesis of Aromatic Polyester Amide

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature increases from 150° C. to 300° C. over five hours while by-produced acetic acid and unreacted acetic anhydride are distilled and is maintained at 300° C. for 30 minutes. Thereafter, a content is taken out from the reactor and is cooled to the room temperature. An obtained solid is ground by a grinder, and powdered aromatic polyester amide A1a is obtained. A flow beginning temperature of aromatic polyester amide A1a is 193° C. Aromatic polyester amide A1a is fully aromatic polyester amide.

Aromatic polyester amide A1a is subjected to solid polymerization by increasing the temperature from the room temperature to 160° C. over two hours and 20 minutes, next increasing the temperature from 160° C. to 180° C. over three hours and 20 minutes, and maintaining the temperature at 180° C. for five hours under a nitrogen atmosphere, and then, is cooled. Next, aromatic polyester amide A1a is ground by a grinder, and powdered aromatic polyester amide A1b is obtained. A flow beginning temperature of aromatic polyester amide A1b is 220° C.

Aromatic polyester amide A1b is subjected to solid polymerization by increasing the temperature from the room temperature to 180° C. for one hour and 25 minutes, next increasing the temperature from 180° C. to 255° C. over six hours and 40 minutes, and maintaining the temperature at 255° C. for five hours under a nitrogen atmosphere, and then, is cooled, and powdered aromatic polyester amide A1 is obtained.

A flow beginning temperature of aromatic polyester amide A1 is 302° C. A melting point of aromatic polyester amide A1 is measured using a differential scanning calorimetry apparatus, and is 311° C. Solubility of aromatic polyester amide A1 with respect to N-methylpyrrolidone at 140° C. is equal to or greater than 1% by mass.

### Preparation of Filler

liquid crystal polymer particles (LCP particles) B1
liquid crystal polymer particles (LCP particles) B2
silica particles ... product name “HARIMIC CR10-20”, manufactured by NIPPON STEEL Chemical & Material Co., Ltd., average particle diameter (D50) 10 µm
hollow particles ... product name “glass bubbles S60HS”, manufactured by 3 M Japan Limited, average particle diameter (D50) 30 µm

The LCP particles B1 and the LCP particles B2 are produced by the following method. LCP Particles B1

1034.99 g (5.5 mol) of 2-hydroxy-6-naphthoic acid, 3012.05 g (21.8 mol) of 4-hydroxybenzoic acid, 13.71 g (0.08 mol) of terephthalic acid, and acetic anhydride and a metal catalyst as a catalyst are put in a reactor comprising a stirring device, a torque meter, a nitrogen gas introduction pipe, a thermometer, and a reflux condenser. Gas in the reactor is substituted with nitrogen gas, then, a temperature increases from a room temperature to 140° C. over 15 minutes while stirring under a nitrogen gas flow, and refluxing is performed at 140° C. for one hour.

Next, the temperature increases from 150° C. to 330° C. over three hours and 30 minutes, then, pressure reduction is performed, and polymerization is performed while by-produced acetic acid and unreacted acetic anhydride are distilled. After polymerization, cooling is performed at the room temperature, and a liquid crystal polymer B1 is obtained.

The liquid crystal polymer B1 is ground using a jet mill (“KJ-200” manufactured by KURIMOTO Ltd.), and LCP particles B1 are obtained. The LCP particles B1 have a median diameter (D50) of 15 µm, a dielectric loss tangent of 0.0014, and a melting point of 318° C.

### LCP Particles B2

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst are put in a reactor comprising a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. A temperature increases from a room temperature to 150° C. over 15 minutes while stirring under a nitrogen gas flow, and refluxing is performed at 150° C. for two hours.

Next, the temperature increases from 150° C. to 310° C. over five hours while by-produced acetic acid and unreacted acetic anhydride are distilled, and a polymerized substance is taken out and is cooled to the room temperature. An obtained polymerized substance increases in temperature from the room temperature to 295° C. over 14 hours, and is subjected to solid polymerization at 295° C. for one hour. After solid polymerization, cooling is performed to the room temperature over five hours, and LCP particles B2 are obtained. The LCP particles B2 have a median diameter (D50) of 10 µm, a dielectric loss tangent of 0.0007, and a melting point of 334° C.

### Production of Copper-Clad Laminate

The aromatic polyester amide A1 (80 g) is added to 920 g of N-methylpyrrolidone, and stirring is performed at 140° C. for four hours under a nitrogen atmosphere. A resin solution in which a concentration of solid contents is 8.0% by mass is obtained.

In Examples 4 to 7, a filler described in Table 1 is mixed with a resin solution based on a content described in Table 1, and is dispersed for 15 minutes using an ultrasound disperser, and a resin dispersion liquid is obtained.

The resin solution or the resin dispersion liquid is coated on an electrolytic copper foil (product name “CF-T9DA-SV-18”, manufactured by FUKUDA Metal Foil & Powder Co., Ltd., surface roughness Sa = 0.22 µm), and is dried at 50° C. for three hours. With this, a resin layer having a thickness of 40 µm is formed on the electrolytic copper foil.

Annealing treatment is performed on a laminate in which the resin layer is formed on the electrolytic copper foil, based on a temperature and a time described in Table 1 in a nitrogen atmosphere, and a copper-clad laminate (laminate) is obtained.

A copper layer is etched from the produced flexible copper-clad laminate to take out a film. A strip-shaped test piece having a width of 2 cm and a length of 8 cm is cut from the taken-out film. A melting calorie, a melting point, and a dielectric loss tangent of the film are measured using the test piece. A measurement method is as follows. A measurement result is shown in Table 1.

### Melting Calorie and Melting Point

The melting calorie and the melting point are measured using a differential scanning calorimeter (product name “DSC-60A Plus”, manufactured by Shimadzu Corporation). A temperature increase rate in the measurement is set to 10° C./minute.

### Dielectric Loss Tangent

A measurement of the dielectric loss tangent is performed by a resonance perturbation method at a frequency of 10 GHz. A 10 GHz cavity resonator (CP531 manufactured by KANTO Electronic Application and Development Inc.) is connected to a network analyzer (“E8363B” manufactured by Agilent Technology Co., Ltd.), the test piece is inserted into the cavity resonator, and the dielectric loss tangent of the film is measured from change in resonance frequency before and after insertion for 96 hours under an environment of a temperature of 25° C. and humidity of 60 %RH.

TABLE 1

| | Aromatic Polyester Amide | Filler | | Annealing Treatment | | Melting Calorie (J/g) | Melting Point (°C) | Dielectric Loss Tangent | Melting Calorie/Melting Point |
|---|---|---|---|---|---|---|---|---|---|
| | | Kind | Content (% by Volume) | Temperature (°C) | Time (h) | | | | |
| Example 1 | A1 | - | - | 270 | 3 | 2.8 | 348 | 0.0049 | 0.0080 |
| Example 2 | A1 | - | - | 280 | 3 | 4.3 | 340 | 0.0044 | 0.0126 |
| Example 3 | A1 | - | - | 300 | 3 | 6.2 | 335 | 0.0042 | 0.0185 |
| Example 4 | A1 | LCP Particles B1 | 50 | 300 | 3 | 7.25 | 345 | 0.0031 | 0.0210 |
| Example 5 | A1 | LCP Particles B2 | 50 | 300 | 3 | 8.1 | 351 | 0.0025 | 0.0231 |
| Example 6 | A1 | Silica Particles | 50 | 300 | 3 | 3.0 | 320 | 0.0026 | 0.0094 |
| Example 7 | A1 | Hollow Particles | 50 | 300 | 3 | 2.8 | 330 | 0.0036 | 0.0085 |
| Comparative Example 1 | A1 | - | - | 270 | 2 | 2.1 | 318 | 0.0060 | 0.0066 |

As shown in Table 1, in Example 1 to Example 7, since the film includes aromatic polyester amide, and the melting calorie is equal to or greater than 2.2 J/g, the film has a low dielectric loss tangent.

On the other hand, in Comparative Example 1, the melting calorie of the film is less than 2.2 J/g, and has a high dielectric loss tangent.

What is claimed is:

1. A film comprising:
an aromatic polyester amide,
the film having a melting calorie equal to or greater than 2.2 J/g.

2. The film according to claim 1,
wherein a melting point of the film is 300° C. to 360° C.

3. The film according to claim 2,
wherein a ratio of the melting calorie to the melting point is equal to or greater than 0.007 J/g· °C.

4. The film according to claim 1,wherein
the aromatic polyester amide comprisesa unit represented by the following Formula 1, a unit represented by the following Formula 2, and a unit represented by the following Formula 3; and
with respect to a total content of the unit represented by Formula 1, the unit represented by Formula 2, and the unit represented by Formula 3,
a content of the unit represented by Formula 1 is 30% by mol to 80% by mol,
a content of the unit represented by Formula 2 is 10% by mol to 35% by mol, and
a content of the unit represented by Formula 3 is 10% by mol to 35% by mol, 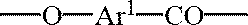 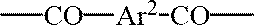 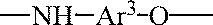
wherein in Formulae 1 to 3, Ar¹, Ar², and Ar³ each independently represent a phenylene group, a naphthylene group, or a biphenylylene group.

5. The film according to claim 1, further comprising a filler.

6. The film according to claim 5,
wherein the filler includes an inorganic filler comprisingat least one selected from the group consisting of boron nitride, titanium dioxide, and silicon dioxide.

7. The film according to claim 5,
wherein the filler includes an organic filler comprising at least one selected from the group consisting of liquid crystalline polyester, polytetrafluoroethylene, and polyethylene.

8. The film according to claim 5,
wherein the filler compriseshollow particles.

9. The film according to claim 5,
wherein the filler comprises liquid crystal polymer particles, silica particles, or glass hollow particles.

10. A laminate comprising:
the film according to claim 1; and
a metal layer or a metal wire that is disposed on at least one surface of the film.
